(19) United States
(12) Patent Application Publication
(10) Pub. No.: US 2010/0150506 A1
(43) Pub. Date: Jun. 17, 2010

(54) POLYMER OPTICAL WAVEGUIDE FORMING MATERIAL, POLYMER OPTICAL WAVEGUIDE AND MANUFACTURING METHOD OF POLYMER OPTICAL WAVEGUIDE

(75) Inventors: Katsumi Maeda, Minato-ku (JP); Kaichiro Nakano, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC Corporation, Minato-ku (JP)

(21) Appl. No.: 12/594,029

(22) PCT Filed: Feb. 29, 2008
(86) PCT No.: PCT/JP2008/053663

§ 371 Date: Jan. 14, 2010

(30) Foreign Application Priority Data
Mar. 30, 2007 (JP) 2007-090795

(51) Int. Cl. G02B 6/02; G02B 6/00; G03F 7/004; G03F 7/20

(52) U.S. Cl. 385/123; 385/143; 385/145; 430/270.1; 430/321

(57) ABSTRACT

There are provided polymer optical waveguide forming material, a polymer optical waveguide and a manufacturing method of the polymer optical waveguide which reduces transmission loss with good processability. The polymer optical waveguide forming material is comprised of a polymer containing norbornene-based structural units including a hydroxy group; a photoacid generator for generating acid by irradiation of an actinic ray; and a monomer component polymerized by acid generated by said photoacid generator.

### TECHNICAL FIELD

The present invention relates to a polymer optical waveguide utilized in an optical element, optical interconnection, an optical circuit board, and an optical and electrical mixture circuit board and the like used in optical communication and optical information processing fields, a polymer optical waveguide forming material for forming the polymer optical waveguide and a manufacturing method of the polymer optical waveguide. This application is based on Japanese Patent Application No. 2007-090795 and claims the benefit of the priority therefrom. All contents of disclosure of this application are incorporated herein by reference.

### BACKGROUND ART

With rapid popularization of the internet and digital home electronics in recent years, there is a demand for larger capacity and higher speed of information processing in communication systems and computers. Thus, high-speed transmission of a large volume of data by a high-frequency signal has been considered. However, when a large volume of a signal is transmitted by the high-frequency signal, a transmission loss is large in the conventional transmission system using an electrical wiring. For this reason, an optical transmission system has been considered. Attempts to use the optical transmission system for wiring for communication between computers, in a device and in a board are being pursued. One of elements for realizing the optical transmission system is an optical waveguide. The optical waveguide is a basic component in an optical element, optical interconnection, an optical wiring board, an optical and electrical mixed circuit board and the like and must be manufactured at low costs to have high performance.

Known optical waveguide includes a quartz waveguide using quartz and a polymer waveguide using a polymer material. The quartz waveguide has a very small transmission loss in a range of wavelength of 600 to 1600 nm which is used in the optical transmission system. However, a processing temperature is high and it is hard to manufacture the waveguide having a large area, which are disadvantageous in terms of manufacturing process and costs.

On the other hand, the polymer waveguide is easy to be processed as it can be made of a photosensitive resin composition. The polymer waveguide has also a high degree of freedom in a materials design. As a material for the polymer waveguide, for example, Japanese Laid-Open Patent Applications Nos. JP-A Heisei 10-170738 and JP-A Heisei 11-337752 describe usage of an epoxy compound. Japanese Laid-Open Patent Application No. JP-A Heisei 9-124793 discloses usage of a polysiloxane compound. Japanese Laid-Open Patent Application No. JP-A 2006-323240 describes usage of a norbornene-based polymer.

However, generally, the polymer waveguide has larger transmission loss in the range of wavelength of 600 to 1600 nm which is used in the optical transmission system than the quartz waveguide. To reduce a transmission loss, use of chemically modified polymers such as deuterated or fluoridated polymers has been considered. However, when attempts to reduce the transmission loss are made, processability as a merit of the polymer waveguide tends to deteriorate and it is difficult to reduce the transmission loss without impairing processability.

### DISCLOSURE OF INVENTION

Therefore, an object of the present invention is to provide a polymer optical waveguide forming material, a polymer optical waveguide and a manufacturing method of the polymer optical waveguide which can reduce a transmission loss while maintaining good processability.

After consideration to attain the above object, the present inventors found that a refractive index suitable for a core layer and a clad layer of the polymer optical waveguide could be provided while keeping an excellent processing accuracy by using a norbornene-based polymer with a specific structure and completed the present invention.

In other words, a polymer optical waveguide forming material according to the present invention includes a polymer containing a norbornene-based structural unit represented by a below-mentioned formula (1), a photoacid generator for generating acid by irradiation of an actinic ray and a monomer component polymerized by the acid generated by the photoacid generator, and the monomer component includes an epoxy compound having an epoxy group:

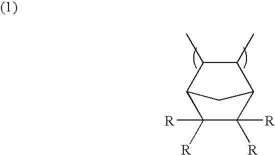

Here, in the formula (1), each of four Rs is any of a hydrogen atom, a hydroxy group and an organic group. At least one of the four Rs is a hydroxy group or an organic group including the hydroxy group.

A polymer optical waveguide according to the present invention includes a core layer and a clad layer disposed so as to surround the core layer. At least one of the core layer and the clad layer is formed of a cured product of the above-mentioned polymer optical waveguide forming material.

A manufacturing method of the polymer optical waveguide according to the present invention includes steps of: preparing the above-mentioned polymer optical waveguide forming material; and irradiating the polymer optical waveguide forming material with an actinic ray so that the polymer optical waveguide forming material may be cured.

According to the present invention, the polymer optical waveguide forming material, the polymer optical waveguide and the manufacturing method of the polymer optical waveguide, which can reduce the transmission loss while maintaining good processability, are provided.

### BRIEF DESCRIPTION OF DRAWINGS

FIG. 1A is a step sectional view for illustrating a manufacturing method of a polymer optical waveguide;

FIG. 1B is a step sectional view for illustrating the manufacturing method of the polymer optical waveguide;

FIG. 1C is a step sectional view for illustrating the manufacturing method of the polymer optical waveguide;

FIG. 1D is a step sectional view for illustrating the manufacturing method of the polymer optical waveguide;

FIG. 1E is a step sectional view for illustrating the manufacturing method of the polymer optical waveguide;

FIG. 1F is a step sectional view for illustrating the manufacturing method of the polymer optical waveguide; and

FIG. 1G is a step sectional view for illustrating the manufacturing method of the polymer optical waveguide.

### BEST MODE FOR CARRYING OUT THE INVENTION

A preferred embodiment of a polymer optical waveguide forming material, a polymer optical waveguide and a manufacturing method of the polymer optical waveguide according to the present invention will be described below.

(Polymer Optical Waveguide Forming Material)

First, the polymer optical waveguide forming material will be described. The polymer optical waveguide forming material in the present embodiment includes at least a polymer, a photoacid generator and a monomer.

The polymer contains at least a norbornene-based structural unit represented by a below-mentioned formula (2):

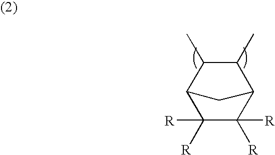

Here, in the formula (2), each of four R is any of a hydrogen atom, a hydroxy group and an organic group, and at least one of the four R is a hydroxy group or an organic group including a hydroxy group.

A basic skeleton of such a norbornene-based structural unit does not include a double bond, an aromatic ring, or the like. Accordingly, when such material is used, coloring of the polymer optical waveguide which is caused when forming the polymer optical waveguide can be prevented. Since a functional group absorbing light is not included, a transmission loss can be reduced.

It is preferred that the norbornene-based structural unit is a structural unit represented by a below-mentioned formula (3):

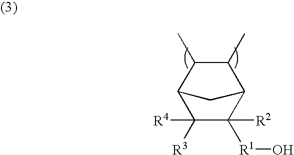

In the formula (3), R¹ represents any of a single bond, an alkylene group and a group expressed by —COO—X— (X is a saturated chain hydrocarbon group). Examples of the alkylene group include a methylene group, an ethylene group, a propylene group, a butylene group. Examples of the group expressed by —COO—X— include a group expressed by —COO(CH₂)n- (n is a natural number), —COOCH(OH₃)CH₂— and —COOCH₂CH(CH₃)—. Examples of the group expressed by —COO(CH₂)n- include —COOCH₂—, —COOOCH₂CH₂—, —COOCH₂CH₂CH₂— and —COO(CH₂)₄— and the like.

In the formula (3), R² to R⁴ are each independently a hydrogen atom, an alkyl group, a hydroxy alkyl group, an ester group and an acetate group. Examples of the alkyl group include a methyl group, an ethyl group, a propyl group, a butyl group, and the like. Examples of the hydroxy alkyl group include a hydroxy methyl group, a hydroxy ethyl group, a hydroxy propyl group, a hydroxy butyl group, and the like. Examples of the ester group include a methyl ester group, an ethyl ester group, and the like.

More specifically, the norbornene-based structural unit represented by the formula (3) may be structural units represented by a below-mentioned formula (4), but not limited to these units.

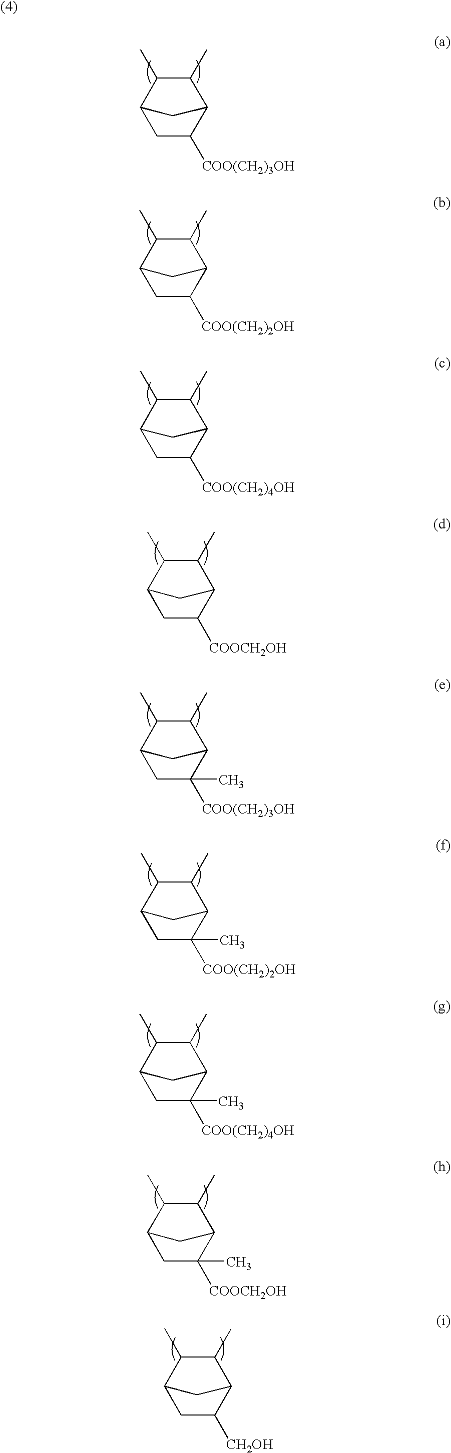

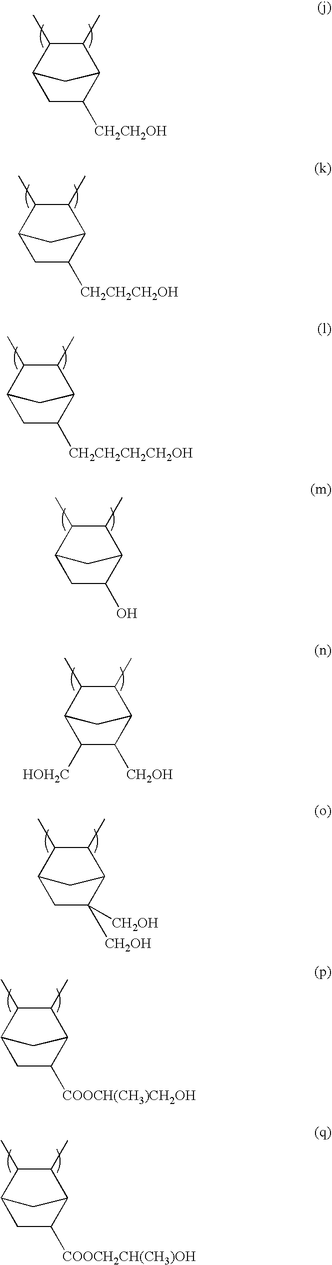

The polymer having the norbornene-based structural unit in the present embodiment can be obtained by preparing a norbornene derivative providing the norbornene-based structural unit after polymerization as a material monomer and polymerizing the norbornene derivative according to a publicly known polymerization method such as addition polymerization. In the case of addition polymerization, for example, a method described in Macromolecules, volume 29, pages 2755 to 2763 (1996) can be adopted. At this time, a palladium compound or a nickel compound may be used as a catalyst for the production. Examples of the palladium compound include, for example, (η³-allyl) Pd(BF₄) (η³-allyl) Pd(SbF₆), [Pd(CH₃CN)₄] [BF₄]₂, and the like. Examples of the nickel compound include [bis (pentafluorophenyl) nickel toluene complex] and the like. A manufacturing method using the nickel compound includes, for example, a method of T. Chiba et al. which is described in Journal of Photopolymer Science and Technology, volume 13 (No. 4), pages 657 to 664 (2000). It is desired to refine the product after polymerization according to a publicly known refining method to remove an unreacted monomer, a polymerization initiator and the like.

The polymer in the present embodiment may be a copolymer containing at least one type of structural unit other than the norbornene-based structural unit represented by the above-mentioned formula (2). Examples of the structural units other than the norbornene-based structural unit represented by the above-mentioned formula (2) include structural units ((a) to (d) in the formula (5)) having the norbornene skeleton, structural units having a tetracyclododecene skeleton ((e) to (g) in the formula (5)), a structural unit having a tricyclononene skeleton ((h) in the formula (5)) and a structural unit having an ethylene skeleton ((i) in the formula (5)) as shown in the below-mentioned formula (5). However, the structural unit other than the norbornene-based structural units represented by the above-mentioned formula (2) is not limited to these structural units.

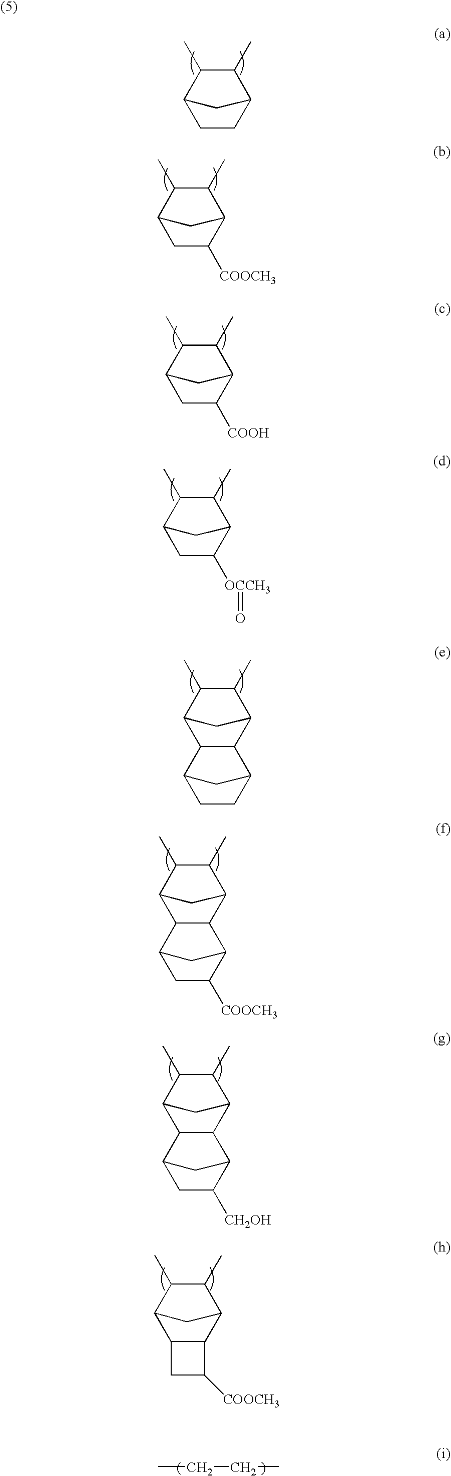

It is preferred that the norbornene-based structural unit according to the above-mentioned formula (2) which is contained in the polymer is equal to 10 mole % or more and to 100 mole % or less of all structural units in the polymer. When the content amount of the norbornene-based structural unit is less than 10 mole %, a sufficient amount of cured material may not be formed. When the content mount of the norbornene-based structural unit is less than 10 mole %, it is difficult to obtain an effect of reducing the transmission loss.

The weight average molecular weight (Mw) of the polymer is preferably 1×10³ to 1×10⁶, more preferably 4×10³ to 5×10⁵.

Next, a component of the photoacid generator in the present embodiment will be described. The photoacid generator is not specifically limited as long as it generates acid due to irradiation of an actinic ray. However, it is preferred that a uniform applied film can be formed using the polymer optical waveguide forming material.

Examples of the specific usable photoacid generator include, but not limited to, for example, a triarylsulfonium salt derivative, a diaryliodonium salt derivative, a dialkylphenacylsulfonium salt derivative, a nitrobenzylsulfonate derivative, an N-hydroxy naphthalimide sulfonic acid ester, an N-hydroxy succinimide sulfonic acid ester derivative, and the like. Among them, the triarylsulfonium salt derivative is preferable from the view point in that it has a high thermal stability and an excellent acid generation efficiency. Examples of the triarylsulfonium salt derivative include, for example, a 4-thiophenoxyphenyl diphenyl sulfonium hexa-fluoro antimonate, a 4-thiophenoxyphenyl diphenyl sulfonium hexa-fluoro phosphate, and the like. The photoacid generator may be used singly or as a mixture of two or more kinds.

From the view point of achieving sufficient sensitivity at irradiation of the actinic ray and enabling suitable pattern formation, a content rate of the photoacid generator is preferably 0.05% by mass or more, and more preferably 0.1% by mass or more based on the total amount of the above polymer, photoacid generator, and monomer. Meanwhile, from the view point of forming the uniform applied film and maintaining transmission characteristics of the polymer optical waveguide, the content rate of the photoacid generator is preferably 15% by mass or less, and more preferably 7% by mass or less based on the total amount of the above-mentioned polymer, photoacid generator, and monomer.

Next, a monomer component will be described. The monomer component in the present embodiment is polymerized by an acid component generated by the photoacid generator at irradiation of the actinic ray. The monomer component contains an epoxy compound having an epoxy group. The epoxy group contained in the epoxy compound undergoes a cross-linking reaction with the hydroxy group contained in the polymer upon irradiation of the actinic ray. For this reason, a curing efficiency upon irradiation of the actinic ray can be improved.

The epoxy compound includes at least one compound selected from a group including, for example, bisphenol A diglycidyl ether, bisphenol A propoxylate diglycidyl ether, hydrogenated bisphenol A diglycidyl ether, ethylene glycol diglycidyl ether, diethylene glycol diglycidyl ether, propylene glycol diglycidyl ether, tripropylene glycol diglycidyl ether, neopentylglycol diglycidyl ether, 1,6-hexanediol diglycidyl ether, glycerin diglycidyl ether, trimethylolpropane triglycidyl ether, 1,2-cyclohexane carboxylic acid diglycidylester, 3,4-epoxycyclohexane carboxylic acid 3,4-epoxycyclohexyl methyl, tris(epoxypropyl) isocyanurate, 2-epoxyethylbicyclo[2.2.1]heptyl glycidyl ether, ethylene glycol bis(2-epoxyethylbicyclo[2.2.1]heptyl)ether, bis(2-epoxyethylbicyclo[2.2.1]heptyl)ether, a diglycidyl ether end of poly (dimethyl siloxane) and 1,3-bis(3-glycidoxypropyl) tetramethyl disiloxane. The epoxy compound may be used singly or as a mixture of two or more kinds.

Such an epoxy compound is preferably contained in a range of from 0.5 to 80% by mass, and more preferably from 1 to 70% by mass based on the total amount of the polymer, the photoacid generator and the monomer component contained in the polymer optical waveguide forming material. When the content amount of the epoxy compound is small, an effect of improving the curing efficiency due to a cross-linking reaction between the hydroxy group and the epoxy group in the polymer cannot be sufficiently obtained. Meanwhile, the content amount of the epoxy compound is large, the content amount of the polymer is necessarily decreased and thus, the effect of improving the curing efficiency due to the cross-linking reaction cannot be sufficiently obtained.

The above-mentioned monomer component may contain components other than the epoxy compound. Examples of the components other than the epoxy compound include an oxetane compound. The oxetane compound quickly starts polymerization initiation reaction upon irradiation of the actinic ray, which can improve the curing efficiency. An example of the oxetane compound includes, for example, a compound with a carbon number of 6 to 20. Such the oxetane compound includes, for example at least one compound selected from a group including 3-ethyl-3-hydroxy methyloxetane, 1,4-bis{[(3-ethyl-3-oxetanyl)methoxy]methyl}benzene, 3-ethyl-3-(phenoxymethyl) oxetane, di[1-ethyl (3-oxetanyl)]methyl ether, 3-ethyl-3-(2-ethylhexyloxymethyl) oxetane and 3-ethyl-3-{[3-(triethoxysilyl) propoxy]methyl}oxetane. In the group, 1,4-bis{[(3-ethyl-3-oxetanyl)methoxy]methyl}benzene is more preferable from the view point of a thermal stability of the curing material. The oxetane compound may be used singly or as a mixture of two or more kinds.

When the oxetane compound is contained as the monomer component, the content rate of the oxetane compound is preferably 0.5 to 80% by mass and more preferably 1 to 50% by mass based on the total amount of the polymer, the photoacid generator and the monomer component. When the content rate of the oxetane compound is too high, the content rates of the epoxy compound and the polymer are decreased and it becomes difficult to obtain an effect of the cross-linking reaction between the epoxy group-hydroxy groups. When the content rate of the oxetane compound is too low, it becomes difficult to obtain an effect of improving efficiency of the effect caused by the oxetane compound.

Various additive agents may be appropriately added to the optical waveguide forming material in the present embodiment within a range not impairing characteristics of the polymer optical waveguide. Examples of the additive agents include fillers, adhesion improvers and application improvers. Appropriate solvents may be added to adjust viscosity and other purpose.

Examples of the above-mentioned filler include at least one filler selected from a group including alumina, silica, glass and metal oxide. By adding these fillers, a crack-resisting property and a heat-resisting property can be improved and warpage of the waveguide can be corrected. A shape of the filler may be any of fibers, beads or powders.

An example of the above-mentioned adhesion improver includes, for example, an organosilicon compound. The organosilicon compound includes, for example, at least one compound selected from a group including 2-[hydroxy (polyethyleneoxy) propyl]heptamethyltrisiloxane, both terminals of polydimethylsiloxane having hydroxy alkyl, γ-aminopropyltrimethoxysilane, γ-aminopropyltriethoxysilane, vinyltriethoxysilane, a compound represented by a below-mentioned formula (6) and a compound represented by the below-mentioned formula (7). However, the organosilicon compound is not limited to these:

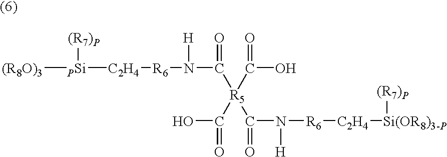

### (Wherein,

R5: tetravalent aromatic group
R6: divalent organic group
R7, R8: monovalent organic group, which are independent from each other, and may be the same or different.

### P is 0, 1 or 2).

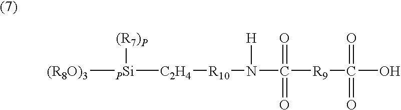

### (Wherein,

R9: divalent aromatic group or divalent organic group
R10: divalent organic group
R11, R12: monovalent organic group, which are independent from each other, and may be the same or different.

### P is 0, 1 or 2).

A solvent used for preparing the above-mentioned polymer optical waveguide forming material is not specifically limited as long as components of the polymer optical waveguide forming material can sufficiently dissolve in the solvent and be uniformly applied by the solution. For example, at least one type of organic solvent selected from a group including γ-butyrolactone, propylene glycol monomethyl ether acetate, propylene glycol monoethyl ether acetate, lactic acid ethyl, 2-heptanone, acetic acid 2-methoxybutyl, acetic acid 2-ethoxyethyl, methyl pyruvate, ethyl pyruvate, 3-methoxy propionic acid methyl, 3-methoxy propionic acid ethyl, N-methyl-2-pyrolidone, cyclohexanone, cyclopentanone, methyl isobutyl ketone, ethylene glycol monomethyl ether, ethylene glycol monomethyl ether acetate, ethylene glycol monoethyl ether, ethylene glycol monoisopropyl ether, diethylene glycol monomethyl ether and diethylene glycol dimethyl ether may be used as the solvent. The solvent may be used singly or as a mixture of two or more types.

The use amount of the solvent is, for example, 20 to 200 parts by mass based on 100 parts by mass of the polymer optical waveguide forming material.

By exposing the above described polymer optical waveguide forming material in the present embodiment due to irradiation of the actinic ray, a photoacid generator contained in the composite generates acid. The acid promotes the cross-linking reaction between the monomer component and the polymer, so that an exposed part is insolubilized in a developer. Then, only an unexposed part is selectively removed by performing development processing and the polymer optical waveguide can be obtained. The polymer optical waveguide thus obtained has a low transmission loss. Furthermore, since exposure and development steps are carried out, the polymer optical waveguide can be manufactured with a high shape accuracy at lower costs.

In addition, since the epoxy compound and the norbornene-based structural unit having the hydroxy group are contained, the cross-linking reaction between the hydroxy group and the epoxy group is caused upon irradiation of the actinic ray. Thereby, a curing efficiency due to irradiation of the actinic ray can be improved. By improving the curing efficiency due to irradiation of the actinic ray, only the cured part can be left with a high accuracy in the development step and the like and a processing accuracy is improved.

Since a double bond, an aromatic ring and the like are not contained in the norbornene skeleton, coloring of the waveguide after curing can be prevented. In other words, the processing accuracy can be improved while suppressing loss at optical transmission.

(Polymer Optical Waveguide)

Next, the polymer optical waveguide in the present embodiment will be described. The polymer optical waveguide is manufactured by using the above-mentioned polymer optical waveguide forming material.

The polymer optical waveguide has a core layer 5 and a clad layer provided such that it surrounds the core layer 5. The clad layer has a lower clad layer 3 and an upper clad layer 6. The core layer 5 is formed on the lower clad layer 3 and the upper clad layer 6 is disposed such that it covers the core layer 5.

In the present embodiment, it is assumed that all of the core layer 5, the lower clad layer 3 and the upper clad layer 6 are made of the above-mentioned polymer optical waveguide forming material having an adjusted refractive index. However, if at least one of the core layer 5, the lower clad layer 3 and the upper clad layer 6 is made of the above-mentioned polymer optical waveguide forming material, an effect to reduce the transmission loss can be achieved. The refractive index can be adjusted by appropriately changing a compounding ratio of the structural unit in the monomer component and the polymer.

A refractive index of the core layer 5 is set to be higher than that of the clad layer. Materials for the core layer 5 and the clad layer can be selected in the following manner respectively. First, a sample obtained by forming a cured layer made of the optical waveguide forming material on a substrate is manufactured. Then, the refractive index of the sample at a predetermined wavelength is measured and, based on the measurement result, it is determined whether or not the material is used for the core layer or the clad layer.

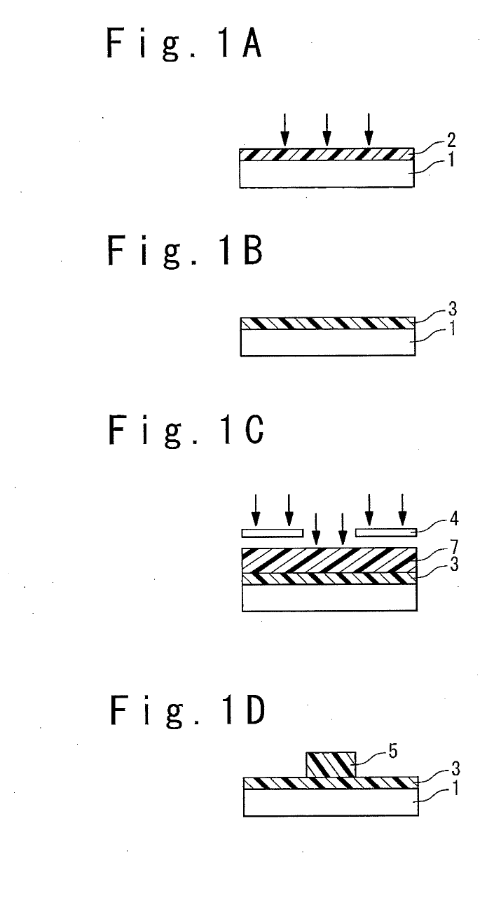

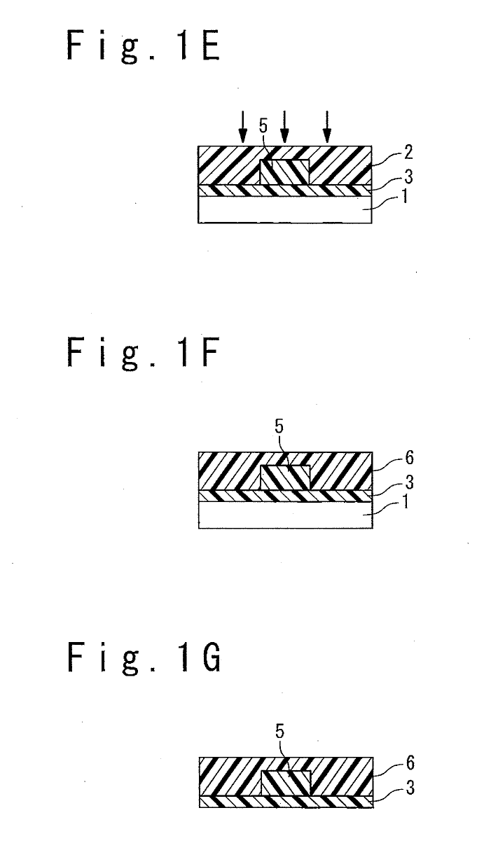

An example of the manufacturing method of the polymer optical waveguide according to the present invention (a forming method of a polymer optical waveguide pattern) will be described below. FIGS. 1A to 1G are step sectional views showing the manufacturing method of the polymer optical waveguide.

First, as shown in FIG. 1A, the polymer optical waveguide forming material is applied onto a substrate 1 and prebaked to form a first waveguide forming material layer 2. Next, by irradiating the whole surface with the actinic ray (hereinafter, which may be referred to as exposure) and performing a heat treatment (baking) step, the first waveguide forming material layer 2 is cured. Thereby, the first waveguide forming material 2 has a low refractive index and the lower clad layer 3 is formed (FIG. 1B). A postbaking step may be performed after the heat treatment step as necessary.

Examples of the substrate 1 include, but not limited to, a silicon substrate, a glass substrate, a quartz substrate, a glass epoxy substrate, a metal substrate, a ceramic substrate, a polymer film and substrates which have a polymer film formed thereon.

A method of applying the polymer optical waveguide forming material is not specifically limited. For example, spin coating using a spin coater, spray coating using a spray coater, immersion, printing, roll coating and the like can be adopted.

Prebaking is a step for drying and removing the solvent of applied polymer waveguide forming material and fixing it on the substrate 1 as the first waveguide forming material layer 2. Prebaking is typically performed at the temperature of from 60 to 160° C.

Examples of the actinic ray used for exposure include an ultraviolet ray, a visible ray, an excimer laser, an electron beam and an X ray. Among them, the actinic ray having a wavelength of 180 to 500 nm is preferable.

The heat treatment step after exposure is typically performed in air or under inert gas atmosphere at the temperature of from 90 to 160° C. The postbaking step is performed in air or under inert gas atmosphere at the temperature of from 90 to 200° C. The postbaking step may be performed in one stage or multistage.

Next, as shown in FIG. 10, the solution, of the polymer optical waveguide forming is applied onto the lower clad layer 3 and prebaked to form a second waveguide forming material layer 7. The polymer optical waveguide forming material selected and used here is a material having a higher refractive index than the refractive index of the material for the lower clad layer 3.

A method of applying the polymer optical waveguide 10, forming material is not specifically limited. For example, the spin coating using the spin coater, the spray coating using the spray coater, the immersion, the printing, the roll coating and the like can be adopted. The prebaking step is a step for drying the applied polymer optical waveguide forming material to remove the solvent and fixing it as the second waveguide forming material layer 7. The prebaking step is typically performed at the temperature of from 60 to 160° C.

Next, a region of the second waveguide forming material layer 7 where the core layer 5 is to be formed is irradiated with the actinic ray through a photo mask (hereinafter, which may be referred to as pattern exposure). By performing heat treatment and development with an organic solvent after pattern exposure, an unexposed part is removed. Then, by performing postbaking, as shown in FIG. 1D, the core layer 5 having a high refractive index is formed on the lower clad layer 3.

The pattern exposure step is a step for selectively exposing a predetermined region of the waveguide forming material layer 7 through the photo mask 4 and transferring a waveguide pattern on the photo mask 4 to the waveguide forming material layer 7. Although an ultraviolet ray, a visible ray, an excimer laser, an electron beam, an X ray and the like may be used as the actinic ray used for pattern exposure, an actinic ray having a wavelength of 180 to 500 nm is preferable. The heat treatment step after pattern exposure is typically performed in air or under inert gas atmosphere at the temperature of from 90 to 160° C.

The development step is a step for dissolving and removing the unexposed part on the waveguide forming material layer 7 with the organic solvent and forming a pattern which becomes the core layer 5. Through the above-mentioned pattern exposure and heating treatment after exposure, a difference between the exposed part and the unexposed part of the waveguide forming material layer 7 in solubility to the developer (dissolution contrast) occurs. By utilizing the dissolution contrast, the unexposed part of the waveguide forming material can be selectively dissolved and removed to obtain the pattern which becomes the core layer 5. At least one type of solution selected from a group including γ-butyrolactone, propylene glycol monomethyl ether acetate, propylene glycol monoethyl ether acetate, lactic acid ethyl, 2-heptanone, acetic acid 2-methoxybutyl, acetic acid 2-ethoxyethyl, methyl pyruvate, ethyl pyruvate, 3-methoxy propionic acid methyl, 3-methoxy propionic acid ethyl, N-methyl-2-pyrolidone, cyclohexanone, cyclopentanone, methyl isobutyl ketone, ethylene glycol monomethyl ether, ethylene glycol monomethyl ether acetate, ethylene glycol monoethyl ether, ethylene glycol monoisopropyl ether, diethylene glycol monomethyl ether and diethylene glycol dimethyl ether may be used as the organic solvent used for development. Methods such as dipping, puddle, immersion, spray and the like can be used as the developing method. After the development step, the formed pattern is rinsed with water or the organic solvent used for development.

The postbaking step is performed in air or under inert gas atmosphere at the temperature of from 90 to 200° C. The postbaking step may be performed in one stage or multistage.

Next, as shown in FIG. 1E, a same polymer optical waveguide forming material as the material used for the lower clad layer 3 is applied onto the lower clad layer 3 with the core layer 5 formed thereon. By performing prebaking, exposure of the whole surface to the actinic ray and heat treatment as in forming of the lower clad layer 3, the upper clad layer 6 is formed (FIG. 1F).

In this manner, the polymer optical waveguide having a structure in which the core layer 5 having the high refractive index is surrounded by the lower clad layer 3 and the upper clad layer 6 having low refractive index respectively is manufactured. A structure as shown in FIG. 1G may be achieved thereafter by removing the substrate 1 by etching or the like. When a highly flexible polymer film is used as the substrate 1, a flexible polymer optical waveguide can be obtained.

As described above, the polymer optical waveguide forming material according to the present invention can obtain a high curing efficiency due to the cross-linking reaction between the hydroxy group and the epoxy group upon irradiation of the actinic ray. Thereby, contrast between the exposed part and the unexposed part is improved, resulting in a high processing accuracy.

Since the double bond, the aromatic ring and the like are not included in the norbornene-based structural unit contained in the polymer, coloring of the cured product can be prevented. As a result, when the optical waveguide is formed, an excellent optical transmission characteristic can be obtained.

### EXAMPLES

The present invention will be described in more detail below using Examples.

### (Synthesis of Norbornene Derivative)

A mixture of norbornene derivatives A1 and A2 and a norbornene derivative B were prepared in the following manner.

### (Preparation of Mixture of Norbornene Derivatives A1 and A2)

The mixture of the norbornene derivatives A1 and A2 having a structure represented by the below-mentioned formula (8) (A1: 2-(2-hydroxy-1-methyl ethyloxycarbonyl)-5-norbornene, A2: 2-(2-hydroxy-propyloxycarbonyl)-5-norbornene) were synthesized in a following manner.

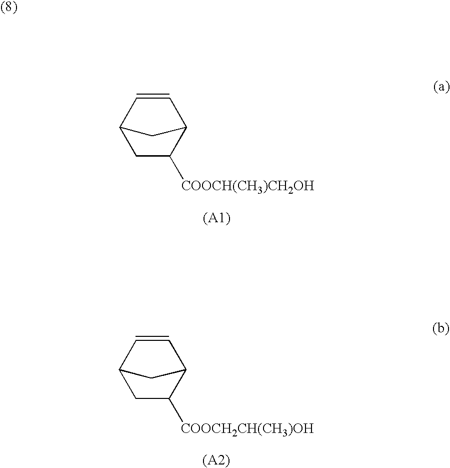

100 g of hydroxypropylacrylate (manufactured by Tokyo Chemical Industry Co., Ltd., product code A0744, mixture of 2-hydroxy-1-methyl ethylacrylate and 2-hydroxypropylacrylate) was dissolved in 100 ml of methylene chloride. 55.87 g of cyclopentadiene (dicyclopentadiene was pyrolyzed by heating and stirring at 165° C. and distilled) was added dropwise and stirred at room temperature for five days. The reaction mixture was concentrated under reduced pressure and further distilled under reduced pressure (104° C./1 mmHg) to obtain 132.79 g of the mixture of the norbornene derivatives A1 and A2 represented by the above-mentioned formula (8). The obtained mixture was colorless fluid and its yield was 88%.

### (Preparation of Norbornene Derivative B)

The norbornene derivative B (2-(hydroxy ethyloxycarbonyl)-5-norbornene) having a structure represented by a below-mentioned formula (9) was synthesized in the following method:

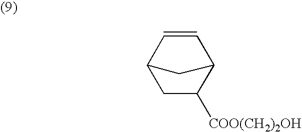

62.62 g of cyclopentadiene was added dropwise in 100 g of hydroxy ethylacrylate and stirred at a room temperature for five days. 141 g of norbornene derivative B represented by the above-mentioned formula 12 was obtained by distilling the reaction mixture under reduced pressure. The obtained norbornene derivative B was colorless fluid and its yield was 90%.

### (Synthesis of Polymer)

A polymer A and a polymer B were synthesized using the norbornene derivative obtained according to the above-mentioned methods.

### (Synthesis of Polymer A)

The polymer A containing 100 mole % of structural units A1a and A2a in total represented by a below-mentioned formula (10) was synthesized in a following method. The structural unit A1a represented by the formula (10) is a norbornene-based structural unit in which one R is —COOCH(CH₃)CH₂OH and the other Rs are hydrogen atoms in the formula (2). The structural unit A2a is a norbornene-based structural unit in which one R is —COOCH₂CH(CH₃)OH and the other Rs are hydrogen atoms in the formula (2):

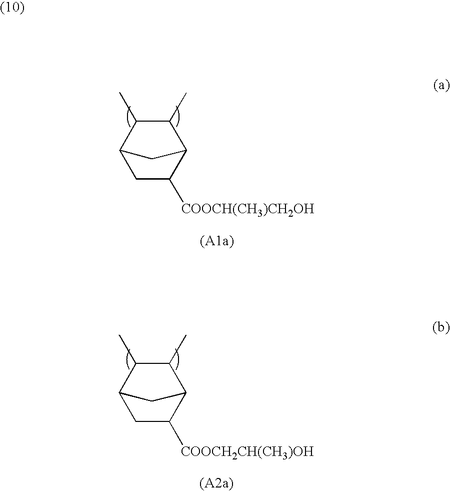

1.1187 g of di-μ-chlorobis [(η3-allyl) palladium (II)] and 2.1011 g of silver hexafluoroantimonate were dissolved in 30 ml of methylene chloride and stirred at room temperature. After a lapse of 20 minutes, the reaction mixture was filtered. This filtrate was mixed with a solution obtained by dissolving 30 g of the mixture of the norbornene derivatives A1 and A2 in 100 ml of methylene chloride, and stirred at room temperature for four days. After that, the reaction mixture was reprecipitated in 700 ml of hexane and deposited resin was filtrated to obtain 30 g of polymer. Next, 30 g of the obtained polymer was dissolved in 170 ml of methanol, and 1.1566 g of sodium borohydride was added to it under ice cooling. The mixture was stirred for 30 minutes and then, left for two hours. A deposited black precipitate was filtrated. The filtrate was poured into 2 L of 0.024N hydrochloric acid and a deposited polymer was filtrated, and further washed in water. The washed polymer was dissolved in 200 ml of tetrahydrofuran and dried with magnesium sulfate, and then the solvent was distilled away under reduced pressure. By adding 100 ml acetone to the residue and reprecipitating the mixture in hexane, 15 g of the target polymer A (polymer shown by the formula (10)) was obtained. Its yield was 50%. When a weight-average molecular weight (Mw) was measured according to the GPC analysis, Mw of the obtained polymer was 6800 (in terms of polystyrene) and dispersity (Mw/Mn) was 2.56.

### (Synthesis of Polymer B)

A polymer containing 100 mole % of the structural unit represented by a below-mentioned formula (11) was synthesized in a following method. That is, this polymer is a polymer including a structural unit in which one R is —COO(CH₂)₂OH and the other Rs are hydrogen atoms in the formula (2):

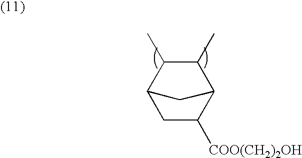

The target polymer B (polymer represented by the formula (11)) was synthesized in the same manner as the manufacturing method of the polymer A except that the norbornene derivative B was used instead of the mixture of the norbornene derivatives A1 and A2. Its total yield was 53%. Mw of the obtained polymer was 7200 (in terms of polystyrene) and dispersity (Mw/Mn) was 2.76.

### First to Fourth Preparation Examples

Polymer optical waveguide forming material solutions (first to fourth preparation examples) having a following composition were prepared using the above-mentioned polymers A, B.

### First Preparing Example

Following components (a) to (d) were mixed to prepare a polymer optical waveguide forming material in a first preparing example.

(a) Polymer; polymer A 2 g

(b) Monomer component; hydrogenated bisphenol A diglycidyl ether 0.6 g

(c) Photoacid generator; 4-thiophenoxyphenyl diphenyl sulfonium hexafluoroantimonate 0.01 g

(d) Solvent; γ-butyrolactone 6.07 g

### Second Preparing Example

Following components (a) to (d) were mixed to prepare a polymer optical waveguide forming material in a second preparing example.

(a) Polymer; polymer A 2 g

(b) Monomer component; bisphenol A propoxylate diglycidyl ether (manufactured by Aldrich Corporation, product code 47575-0) 0.6 g

(c) Photoacid generator; 4-thiophenoxyphenyl diphenyl sulfonium hexafluoroantimonate 0.02 g

(d) Solvent; γ-butyrolactone 6.07 g

### Third Preparing Example

Following components (a) to (e) were mixed to prepare a polymer optical waveguide forming material in a third preparing example.

(a) Polymer: polymer B 2 g

(b) Monomer component: hydrogenated bisphenol A diglycidyl ether 0.6 g

(c) Organosilicon compound: 2-[hydroxy (polyethyleneoxy) propyl]heptamethyl trisiloxane 0.09 g

(d) Photoacid generator: 4-thiophenoxyphenyl diphenyl sulfonium hexafluoroantimonate 0.01 g

(e) Solvent; γ-butyrolactone 6.07 g

### Fourth Preparing Example

Following components (a) to (e) were mixed to prepare a polymer optical waveguide forming material in a fourth preparing example.

(a) Polymer; polymer B 2 g

(b) Monomer component; bisphenol A propoxylate diglycidyl ether 0.6 g

(c) Monomer component; 1,4-bis{[(3-ethyl-3-oxetanyl)methoxy]methyl}benzene (manufactured by TOAGOSEI CO., LTD., product code: XDO) 0.06 g

(d) Photoacid generator; 4-thiophenoxyphenyl diphenyl sulfonium hexafluoroantimonate 0.02 g

(e) Solvent; γ-butyrolactone 6.07 g

The polymer optical waveguide forming material in each of the preparation examples was filtered after mixing using 0.45 μm of filter made of Teflon (registered trademark).

### (Measuring Method of Refractive Index and Results)

The polymer optical waveguide forming material of each of first to fourth preparation examples was applied onto a 4-inch silicon substrate by spin coating and prebaked in an oven at 100° C. for 10 minutes to form an applied film. Next, the applied film was exposed to an ultraviolet ray (wavelength λ=350 to 450 nm) over the entire surface, heated at 100° C. for 10 minutes and then, postbaked at 150° C. for 30 minutes.

Next, for each of the preparation examples, a refractive index at 633 nm was measured using a prism coupler manufactured by Metricon Corporation.

As a result, a refractive index of a film to which the first preparing example was applied was 1.528.

A refractive index of a film to which the second preparing example was applied was 1.540.

A refractive index of a film to which the third preparing example was applied was 1.527.

A refractive index of a film to which the fourth preparing example was applied was 1.5409.

### (Polymer Optical Waveguide)

Subsequently, polymer optical waveguides (fifth and sixth preparation examples) were formed using the above-mentioned polymer A, B and a transmission loss was measured. Specific contents will be described below.

Following components (a) to (d) were mixed to prepare a clad forming material 1.

(a) Polymer; polymer A 20 g

(b) Monomer component; hydrogenated bisphenol A diglycidyl ether 6 g

(c) Photoacid generator; 4-thiophenoxyphenyl diphenyl sulfonium hexafluoroantimonate 0.1 g

(d) Solvent; γ-butyrolactone 11.14 g

Following components (a) to (d) were mixed to prepare a core layer forming material 1.

(a) Polymer; polymer A 20 g

(b) Monomer component; bisphenol A propoxylate diglycidyl ether (manufactured by Aldrich Corporation, product code 47575-0) 6 g

(c) Photoacid generator; 4-thiophenoxyphenyl diphenyl sulfonium hexafluoroantimonate 0.2 g

(d) Solvent; γ-butyrolactone 9.62 g

Following components (a) to (e) were mixed to prepare a core layer forming material 2.

(a) Polymer; polymer B 20 g

(b) Monomer component; bisphenol A propoxylate diglycidyl ether 6 g

(c) Monomer component; 1,4-bis{[(3-ethyl-3-oxetanyl)methoxy]methyl}benzene

(manufactured by TOAGOSEI CO., LTD., product code: XDO) 0.6 g

(d) Photoacid generator; 4-thiophenoxyphenyl diphenyl sulfonium hexafluoroantimonate 0.2 g

(e) Solvent; γ-butyrolactone 9.62 g

The clad layer forming material 1 and the core layer forming materials 1, 2 were filtered and prepared using a 0.45 μm filter made, of Teflon (registered trademark).

### Fifth Preparing Example

The clad layer forming material 1 was applied onto a 4-inch silicon substrate by spin coating and prebaked in an oven at 100° C. for 10 minutes to form a film having a thickness of 25 μm. Next, the applied film was exposed to an ultraviolet ray (wavelength λ=350 to 450 nm, exposure amount=500 mJ/cm²) over the whole surface, baked in an oven at 100° C. for 10 minutes after exposure and then, postbaked at 150° C. for 30 minutes to form the lower clad layer.

Next, the core forming material 1 was applied onto the lower clad layer 3 by spin coating and prebaked in the oven at 90° C. for 60 minutes to form a film having a thickness of 50 μm. Next, the applied film was exposed to an ultraviolet ray (wavelength λ=350 to 450 nm, exposure amount=300 mJ/cm²) through the photo mask and baked in the oven at 100° C. for five minutes. Next, the film was developed in γ-butyrolactone for four minutes according to the immersion method and subsequently, rinsed with pure water for two minutes. As a result, only the unexposed part was dissolved in developer and removed to obtain a core pattern. Next, the core layer was completely cured by baking at 150° C. for 30 minutes to form the core layer 5.

Subsequently, the clad layer forming material 2 was applied onto the lower clad layer 3 with the core layer 5 formed thereon by spin coating and prebaked in the oven at 90° C. for 60 minutes to form a film having a thickness of 25 μm. Next, the applied film was exposed to an ultraviolet ray (wavelength λ=350 to 450 nm, exposure amount=500 mJ/cm²) over the whole surface. After exposure, it was baked in the oven at 100° C. for 10 minutes and postbaked at 150° C. for 30 minutes to form the upper clad layer 6. Thereby, a polymer optical waveguide in a fifth preparing example was obtained.

### Sixth Preparing Example

The core layer forming material 2 was used as the core layer 5 in place of the core layer forming material 1 to obtain a polymer optical waveguide in a sixth preparing example. The same processing as in the fifth preparing example was carried out except that the core layer forming material used was different.

An end face of each of the obtained polymer optical waveguides (fifth and sixth preparation examples) was diced by using a dicer and a transmission loss was evaluated according to a cutback method at wavelength 850 nm. As a result, a transmission loss of the polymer optical waveguide in the fifth preparing example was 0.15 dB/cm On the other hand, a transmission loss of the polymer optical waveguide in the sixth preparing example was 0.16 dB/cm.

When the cross-sectional shape of the core layer was observed, the cross-sectional shapes of both the polymer optical waveguides in the fifth and sixth preparation examples were rectangular, and it was confirmed that processing was done successfully.

1. A polymer optical waveguide forming material, comprising:
a polymer including norbornene-based structural units represented by the following formula (1): 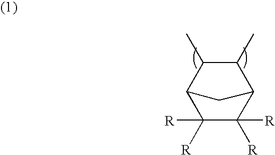
where the four Rs are each any of a hydrogen atom, a hydroxy group and an organic group, and at least one of the four Rs is a hydroxy group or an organic group including a hydroxy group the Formula (1);
a photoacid generator for generating acid by irradiation of an actinic ray; and
a monomer component polymerized by acid generated by said photoacid generator,
wherein said monomer component includes epoxy compound having an epoxy group.

2. The polymer optical waveguide forming material according to claim 1, wherein said norbornene-based structural units are structural units represented by the following formula (2): 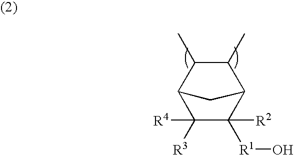
where R¹ represents any of a single bond, an alkylene group and a group expressed by —COO—X—, X being a saturated chain hydrocarbon group, and R² to R⁴ are each any of a hydrogen atom, an alkyl group, a hydroxy alkyl group, an ester group and an acetate group.

3. The polymer optical waveguide forming material according to claim 1, wherein said polymer includes at least one structural unit selected from structural units represented by the following formulas (3) as said norbornene-based structural units:

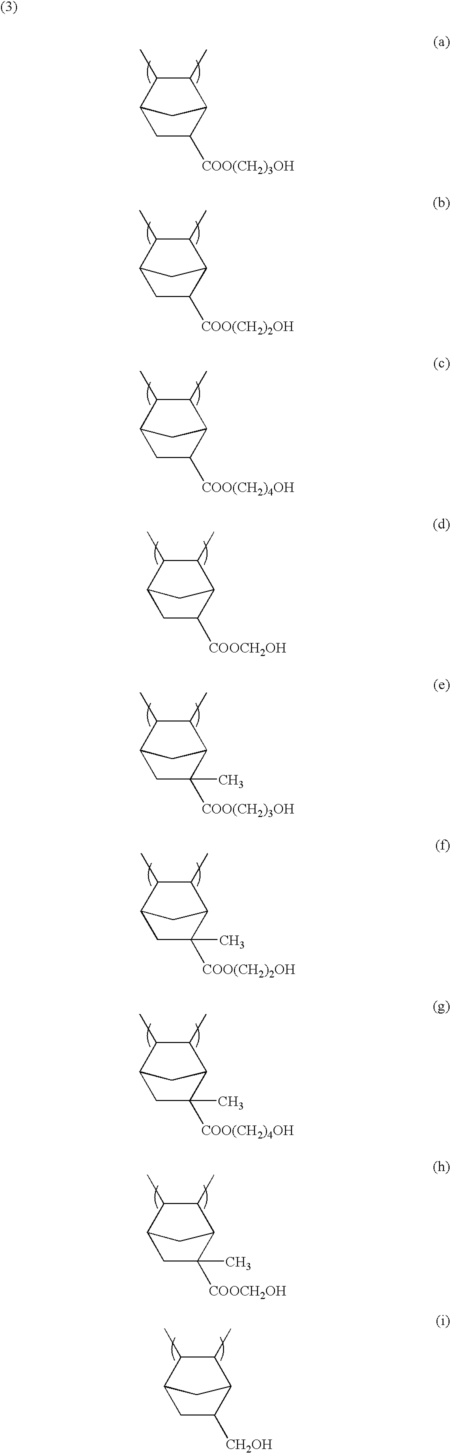

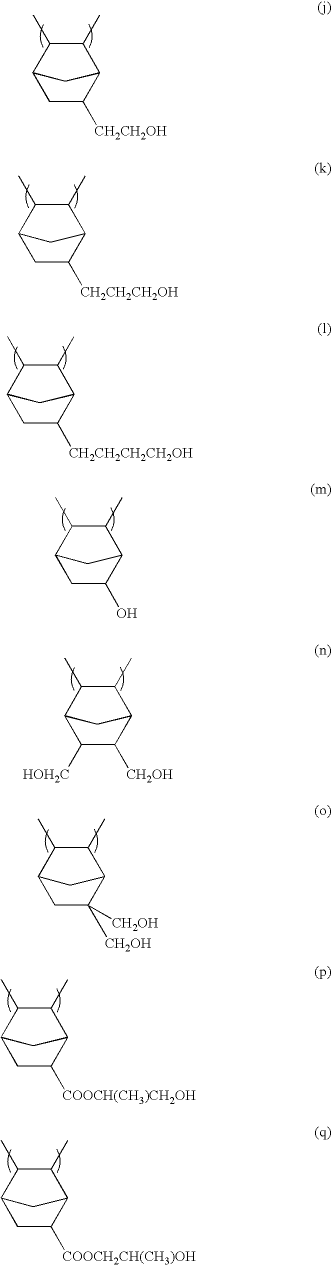

4. The polymer optical waveguide forming material according to claim 1, a wherein concentration of said norbornene-based structural units in said polymer is equal to 10 mole % or more and to 100 mole % or less.

5. The polymer optical waveguide forming material according to claim 1, wherein said epoxy compound includes at least one compound selected from a group consisting of bisphenol A diglycidyl ether, bisphenol A propoxylate diglycidyl ether, hydrogenated bisphenol A diglycidyl ether, ethylene glycol diglycidyl ether, diethylene glycol diglycidyl ether, propylene glycol diglycidyl ether, tripropylene glycol diglycidyl ether, neopentylglycol diglycidyl ether, 1,6-hexanediol diglycidyl ether, glycerin diglycidyl ether, trimethylolpropane triglycidyl ether, 1,2-cyclohexane carboxylic acid diglycidylester, 3,4-epoxycyclohexane carboxylic acid 3,4-epoxycyclohexyl methyl, tris(epoxypropyl) isocyanurate, 2-epoxyethylbicyclo[2.2.1]heptyl glycidyl ether, ethylene glycol bis(2-epoxyethylbicyclo[2.2.1]heptyl)ether, bis(2-epoxyethylbicyclo[2.2.1]heptyl)ether, a diglycidyl ether end of poly (dimethyl siloxane) and 1,3-bis(3-glycidoxypropyl) tetramethyl disiloxane.

6. The polymer optical waveguide forming material according to claim 1, wherein said monomer component includes an oxetane compound.

7. The polymer optical waveguide forming material according to claim 6, wherein said oxetane compound includes a compound with a carbon number of 6 to 20.

8. The polymer optical waveguide forming material according to claim 1, further comprising an adhesion improver.

9. The polymer optical waveguide forming material according to claim 8, wherein said adhesion improver includes an organosilicon compound.

10. The polymer optical waveguide forming material according to claim 1, further comprising at least one filler material selected from a group consisting of alumina, silica, glass and metal oxide.

11. The polymer optical waveguide forming material according to claim 10, the shape of said filler material is any of fibers, beads or powders.

12. A polymer optical waveguide, comprising:
a core layer; and
a clad layer provided to surround said core layer,
wherein at least one of said core layer and said clad layer is formed with a cured product of the polymer optical waveguide forming material as set forth in claim 1.

13. The polymer optical waveguide according to claim 12, wherein said clad layer has a refractive index lower than that of said core layer.

14. A manufacturing method of a polymer optical waveguide, comprising:
a step of preparing polymer optical waveguide forming material as set forth in claim 1; and
irradiating said polymer optical waveguide forming material with an actinic ray so that said polymer optical waveguide forming material is cured.

15. A manufacturing method of a polymer optical waveguide, comprising:
a lower clad layer forming step of forming a lower clad layer on a substrate by coating and curing lower clad forming resin;
a core layer forming step of forming a core layer on a portion of said lower clad layer so that said core layer is in contact with said lower clad layer;
an upper clad layer forming step of forming an upper clad layer on said lower clad layer to cover said core layer,
wherein at least one of said lower clad layer, said core layer and said upper core layer is formed by curing the polymer optical waveguide forming material as set forth in claim 1.

16. The manufacturing method of a polymer optical waveguide according to claim 15, wherein said core layer forming step includes:
applying said polymer optical waveguide forming material on said lower clad layer;
irradiating said polymer optical waveguide forming material with an actinic ray in a region in which said core layer is to be formed, to cure said polymer optical waveguide forming material;
developing an uncured portion of said polymer optical waveguide forming material.
